(19) United States
(12) Patent Application Publication
(10) Pub. No.: US 2015/0179406 A1
(43) Pub. Date: Jun. 25, 2015

(54) ELECTRICAL CIRCUIT TO IMPEDANCE MATCH A SOURCE AND A LOAD AT MULTIPLE FREQUENCIES, METHOD TO DESIGN SUCH A CIRCUIT

(71) Applicants: ECOLE POLYTECHNIQUE, Palaiseau (FR); CENTRE NATIONAL DE LA RECHERCHE SCIENTIFIQUE, Paris (FR)

(72) Inventors: Erik Johnson, Paris (FR); Jean-Paul Booth, Boullay Les Troux (FR)

(21) Appl. No.: 14/408,158

(22) PCT Filed: Jun. 14, 2013
(86) PCT No.: PCT/EP2013/062427

§ 371 Date: Dec. 15, 2014

(30) Foreign Application Priority Data
Jun. 15, 2012 (EP) 12305684.8

(51) Int. Cl. H01J 37/32; G06F 17/50

(52) U.S. Cl. CPC H01J 37/32183; H01J 37/32091; G06F 17/5072

(57) ABSTRACT

A matching circuit is provided to adapt electrical impedance simultaneously for at least one pair of a higher and a lower frequencies between a plasma reactor and a generator; said matching circuit comprises at least a “load and tune” L-type stage, and includes
a “tune circuit” connected in series to the plasma reactor and having at least one of or both an inductor and a capacitor in series;
a “load circuit” connected in parallel to the series-connected “tune circuit” and load, and comprising at least one of or both an inductor and a capacitor in parallel; and the component values of the tune and load circuits are chosen such that, for the lower frequency, the matching circuit follows a negative load reactance path in a Smith chart, and for the higher frequency, the matching circuit follows a positive load reactance path in the Smith chart.

### BACKGROUND OF THE INVENTION

1. Field of the Invention

The present invention relates to the field of impedance matching, and in particular, to the field of plasma processing systems.

2. Description of the Related Art

Capacitively coupled plasma reactors for etching or deposition have been historically excited with a sinusoidal voltage waveform at one frequency (typically radio-frequencies in the 1-900 MHz range). As the characteristic impedance of a capacitively coupled plasma-processing system is complex and variable, and is not typically the same as (and therefore matched to) the output of the power generator (typically 50 Ω resistive), a matching circuit is required to maximize power transfer to the load.

It was later noted that enhanced process performance and control could be achieved by applying voltage waveforms at two (unsynchronised) frequencies to either the powered electrode or the substrate chuck. To apply this concept, two radiofrequency (RF) generators and two independent match boxes are used.

Recently, the use of voltage waveforms consisting of the sum of synchronised harmonics of a base frequency (notably f+2f) applied to one electrode was shown to enable independent control over ion bombardment energy and injected power (the electrical asymmetry effect). To physically implement this configuration for two frequencies requires the use of two power generators, two match boxes, and filtering to isolate the two systems. The advantages of adding additional harmonics have been demonstrated in etching applications and in the growth of thin films. Clearly, as the number of frequencies (n) increases, the number of power generators, matchboxes and filters increases (n for the generators and matchboxes and n(n−1) for the filters), making the above solution impractical. An alternative is to use a single, wideband power source which can produce the multi-frequency waveform directly. Experimental demonstrations of this technique have until now been done without impedance matching (therefore wasting large amounts of power, and limiting the input power to the process).

The electrical impedance seen at the power feedthrough of practical capacitively coupled plasma processing systems (CCP-PS) is typically a small, real impedance (relative to a value of 50Ω) in series with a larger imaginary impedance. This presents a power matching challenge, as for optimal power transfer, RF power generators or amplifiers (and transmission lines/cables) are typically designed to have a characteristic output impedance of 50 Ω or 100Ω. For maximum power transfer, the load attached to the output of the generator or amplifier must have the same characteristic impedance. To solve this problem, one solution is to use electrical matching networks to transform the impedance of the chamber to that of the amplifier. Typical impedance matching circuits for a single frequency comprise simple load and tune-type circuits in one of three different configurations: L-type, (1a), pi-type (1b) or t-type (1c), as shown below in FIG. 1. The load and tune impedances (Z_{LOAD} and Z_{TUNE}) represent the impedances of capacitors (Z=1/jωC) or inductors (Z=jωL) at the frequency of operation of the RF generator.

When it is desired to simultaneously couple multiple frequencies to the CCP-PS (such as for the use of tailored voltage waveforms, which allow the generation of the so-called electrical asymmetry effect) the solution of FIG. 1 is no longer applicable, as the impedance of the CCP-PS will vary with frequency, as will those of the passive components within the matching box. For this reason, a different circuit design must be used.

Accordingly, the present invention is directed to providing a matching circuit and a method for efficiently exciting a plasma reactor at multiple (arbitrary) frequencies using a single (multi-frequency) generator by using a single matchbox and without the need for filtering.

Another object of the invention is to provide a matching circuit design that matches imperfectly the impedance seen by the generator but uses fewer components.

Another object of the invention is to implement a new, tunable multi-frequency matching circuit when the impedance of the reactor is not well known.

### SUMMARY OF THE INVENTION

At least one of the above-mentioned objects is achieved with a matching circuit according to the present invention to adapt electrical impedance simultaneously for at least one pair of frequencies (consisting of a higher and a lower frequency) between a load and a generator. Said matching circuit comprises at least a “load and tune” L-type stage comprising:
a “tune circuit” connected in series with the load and comprising at least one of or both an inductor and a capacitor in series,
a “load circuit” connected in parallel to the series-connected “tune circuit” and load and comprising at least one of or both an inductor and a capacitor in parallel.

According to the invention, the component values of the tune and load circuits are chosen such that, for the lower frequency, the matching circuit follows a negative load reactance path on a Smith chart, and for the higher frequency, the matching circuit follows a positive load reactance path on the Smith chart.

Advantageously, a single, wideband power source which can produce the multi-frequency waveform directly can be used.

With the matching circuit according to the invention, the impedance seen by the generator is adapted so that at multiple frequencies (fₙ), this impedance is similar or equal to the output impedance of the generator, therefore maximizing electrical power transfer between the generator and the load. More generally, the impedance may be matched at any number of frequencies, limited only by the number of components to be included.

The inductors and capacitors are determined such that for each frequency, the power source (the generator) sees the same impedance.

The use of two components, an inductor and a capacitor, in the both the load circuit and the tune circuit, results in a perfect value of load impedance appearing at the output of the generator when the appropriate values are chosen. It is possible to use fewer components but in this case the matching will be not perfect. For example, if the output of the power generator is typically 50 Ω resistive, with fewer components the matching may be imperfect, and result in a load impedance of 45Ω, as seen by the generator.

According to the invention, the load may advantageously be a capacitively coupled plasma reactor. Furthermore, the higher and lower frequencies may be a fundamental frequency with one of its harmonics. The signal applied to the load may consist of the sum of synchronised harmonics of a base frequency, notably f and 2f.

According to the present invention, for each additional pair of frequencies, the matching circuit comprises an additional tune circuit in parallel to the first tune circuit, and an additional load circuit in series with the first load circuit.

The matching circuit may comprise multiple stages connected in series in order to reach the perfect impedance value when it is not possible to achieve this with only one stage. This may be useful because of the load features or the components available for the matching circuit.

In practice, the impedance of the load at the frequencies for which matching is required may not be perfectly known, and/or may be subject to drift. For this reason, at least one of the stage components is adjustable, for example in real time during operation. Preferably, the adjustable component is a capacitor. All the Load and Tune capacitors in the circuits may be adjustable. Moreover, a variable inductor in the Tune circuit may be obtained by splitting the inductor into two standard inductors in series (possessing a total inductance equal to that of the original inductor), and adding an adjustable capacitor in parallel to one of these inductors. Similarly, a variable inductor in the Load circuit may be obtained by adding an adjustable capacitor in parallel with one of two series-connected inductors whose total inductance sums to that of the ideal, calculated value.

In accordance with another aspect of the present invention, there is provided a method for adapting electrical impedance simultaneously for at least a pair of a higher and a lower frequencies between a load and a generator by using a matching circuit; said matching circuit comprises at least a “load and tune” L-type stage comprising:

a “tune circuit” connected in series to the load and comprising at least one of or both an inductor and a capacitor in series,

a “load circuit” connected in parallel to the series-connected “tune circuit” and load, and comprising at least one of or both an inductor and a capacitor in parallel,

the component values of the tune and load circuits are determined such that, for the lower frequency, the matching circuit follows a negative load reactance path in a Smith chart, and for the higher frequency, the matching circuit follows a positive load reactance path in the Smith chart.

According to the invention, the method comprises the step of simultaneously adapting electrical impedance for a fundamental frequency with one of its harmonics as said lower and higher frequencies.

Advantageously in the method according to the invention, for each additional pair of frequencies, an additional tune circuit is added in parallel to the first tune circuit, and an additional load circuit is added in series to the first load circuit.

As a matter of fact, as the frequencies used by the power generator are discrete, each inductor-capacitor-pair of the tune circuit acts as an open circuit for frequencies which are far from its resonant frequency. Similarly, each inductor-capacitor-pair of the load circuit acts as a short-circuit for frequencies which are far from its resonant frequency.

Consequently, the component values of the additional components are calculated by first assuming that the values for the first tune circuit or the first load circuit are infinite or zero impedance respectively, then an iterative process is carried out to correct the additional components' values. A perfect solution may also be obtained by solving for all components simultaneously.

According to the invention, a perfect match for any two frequencies is obtainable in a single stage when:

$$X ( {ω}_{2} ) - \frac{{ω}_{2}}{{ω}_{2} + {ω}_{1}} ( X ( {ω}_{2} ) + X ( {ω}_{1} ) ) \leq {X}_{match}$$

±X_{match} being the two solutions that provide matching in a Smith chart, one following the negative load reactance path, and one following the positive load reactance path; ωᵢ being the i-th angular frequency, and X(ωᵢ) being the reactance of the load at the angular frequency ωᵢ.

It is also provided a system comprising:

a capacitively coupled plasma reactor,

a generator for simultaneously powering the capacitively coupled plasma reactor with at least one pair of a lower and a higher frequencies, said frequencies being a fundamental frequency with one of its harmonics,

a matching circuit to adapt electrical impedance simultaneously for the fundamental frequency and one of its harmonics between the generator and the capacitively coupled plasma reactor; said matching circuit comprises at least a “load and tune” L-type stage comprising:

a “tune circuit” connected in series to the load and comprising at least one of or both an inductor and a capacitor in series,

a “load circuit” connected in parallel to the series-connected “tune circuit” and load, and comprising at least one of or both an inductor and a capacitor in parallel,

the component values of the tune and load circuits are chosen such that, for the lower frequency, the matching circuit follows a negative load reactance path in a Smith chart, and for the higher frequency, the matching circuit follows a positive load reactance path in the Smith chart.

The foregoing and other objects, features and advantages of the present invention will become more readily apparent from the following detailed description of a preferred embodiment of the invention which proceeds with reference to the accompanying drawings.

### BRIEF DESCRIPTION OF THE DRAWINGS

FIG. 1a is a schematic view illustrating two component matching circuits of L type, according to prior art,

FIG. 1b is a schematic view illustrating three component matching circuits of pi-type, according to prior art,

FIG. 1c is a schematic view illustrating three component matching circuits of t-type, according to prior art,

FIG. 2 illustrates a Smith chart for matching circuit including “negative load reactance” and “positive load reactance” path solutions, using a simple load+tune-type circuit, according to the invention,

FIG. 3 is a schematic view illustrating the matching circuit with component types for matching at two frequencies, according to the invention,

FIG. 4 is a schematic view illustrating the matching circuit with component types for matching at four frequencies, according to the invention,

FIG. 5 is a schematic view illustrating the Smith chart for the matching circuit of FIG. 4,

FIGS. 6a, 6b and 6c: FIG. 6a) is a circuit diagram illustrating chamber impedance and multi-frequency matching circuit, and FIG. 6b) is a graph of frequency dependence of magnitude (gb) and phase (gy) of impedance as seen at reactor feedthrough, and FIG. 6c) as seen by source when using multi-frequency matching circuit,

FIG. 7 is a schematic view illustrating two stages to improve robustness of design and to enable matching on systems with very high negative reactance,

FIG. 8 is the Smith Chart showing impedance progression at two frequencies using a two-stage circuit such as in FIG. 7,

FIG. 9 is a schematic view illustrating a matching circuit containing a reduced number of components giving an imperfect matching, but still much better than with no matching circuit, for two frequencies,

FIG. 10 is the Smith Chart for an impedance matching circuit as in FIG. 3 but using only an inductor in the Tune circuit,

FIG. 11 is the Smith Chart for an impedance matching circuit as in FIG. 3 but using only a capacitor in the Load circuit, and

FIG. 12 is a schematic view illustrating a matching circuit containing adjustable capacitors for correcting matching in case of varying or unknown chamber impedance.

### DETAILED DESCRIPTION

Reference is now made to the drawing figures, in which like numerals or terms refer to like elements throughout the several views.

The Smith chart is a nomogram showing the value of the real part and the imaginary part of impedance. The graph thus consists of a network of a circle or arc.

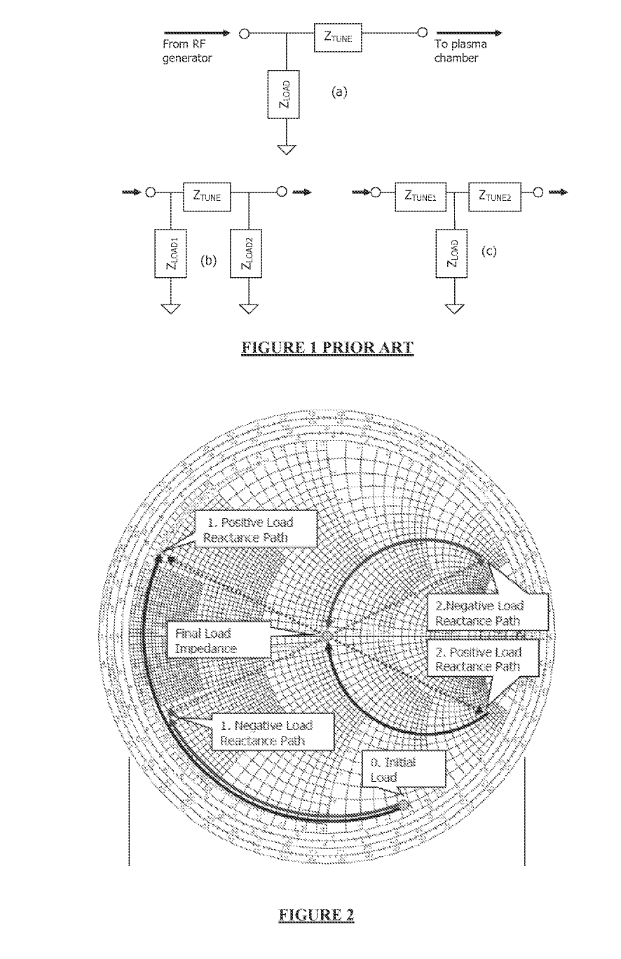

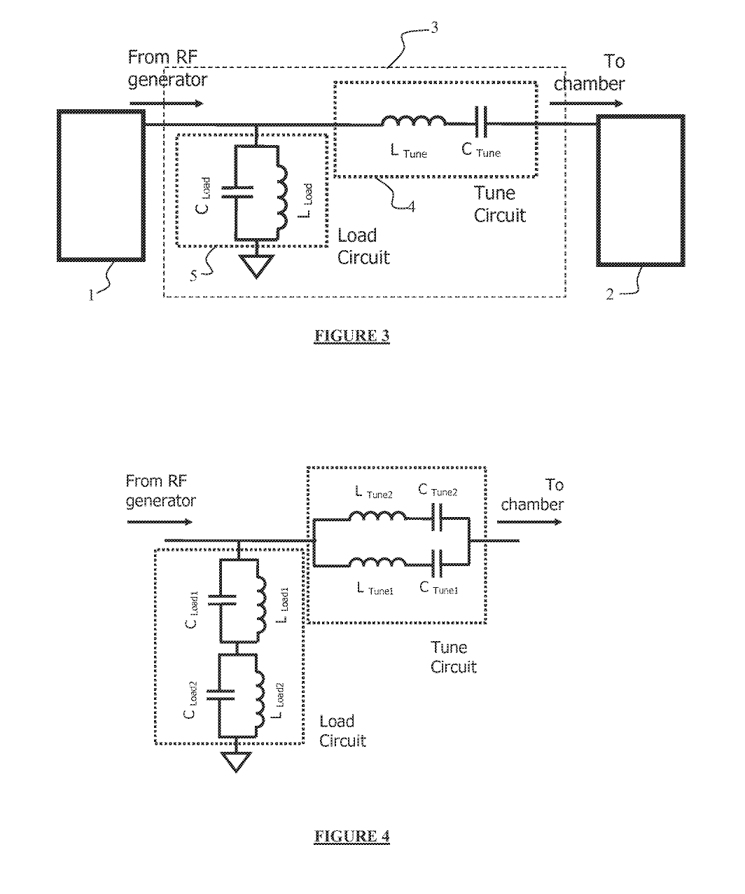

The Smith chart is used to assist in solving problems with transmission lines and matching circuits. It can be used to represent many parameters including impedances, admittances, reflection coefficients, scattering parameters, noise figure circles, constant gain contours and regions for unconditional stability, including mechanical vibrations analysis. The Smith chart is plotted on the complex reflection coefficient plane in two dimensions and is scaled in normalised impedance (the most common), normalised admittance or both, using different colours to distinguish between them. The most commonly used normalization impedance is 50 ohms which is arranged on the horizontal line and illustrated by a small circle on FIG. 2. According to the invention, the Smith chart is used to determine values of components used in the matching circuit.

FIG. 2 illustrates a Smith chart showing two solutions to reach a final load impedance which is for example 50 Ω.

The present invention makes use of the fact that, for a given (single) frequency of operation, when choosing components for a two component match box (such as in FIG. 1a), there are in fact two solutions that will both provide matching, one which follows the “negative load reactance” path, and one which follows the “positive load reactance” path. The “negative load reactance” solution is the one for which the impedance added in series to the load results in the sum of the two having a negative reactance, whereas the inverse is true for the “positive load reactance” solution. This principle is shown in FIG. 2, where the clockwise arrows out of the “Initial Load Impedance” point represent the effect of adding an impedance in series, the dotted line shows the reflection through the origin (to view the impedance as an admittance), and the last arrows represent the addition of an admittance in parallel.

The present invention comprises a two port, passive electrical circuit (dubbed a multi-frequency matching box, MFMB) to adapt the electrical impedance of a capacitively coupled plasma processing system (CCP-PS) so that at multiple frequencies (fₙ), the input impedance is similar or equal to the output impedance of the power source, therefore maximizing electrical power transfer.

The points indicated on FIG. 2 as “1. Positive Load Reactance Path” and “1. Negative Load Reactance Path” are points ±x_{match} (normalised), for the ideal solution to the matching problem. These points correspond to normalized impedances (z=r+ix) for which the real part g of the normalized admittance (y=1/z=g+i b) is equal to 1. The position of these points depend on the normalized resistance, r, of the circuit to be matched, and can be calculated as

x_{match}²=r−r²

From this principle, a simple circuit can be constructed to match simultaneously a given pair of frequencies, where the “Tune Circuit” is a series connected inductor-capacitor pair, and the “Load Circuit” consists of a parallel-connected inductor-capacitor pair. Such a circuit is shown in FIG. 3, and the component values are chosen in the following way:
for any set of two frequencies at which the match should be made, the two sets of two components (pairs of one inductor and one capacitor) are chosen such that at the lower frequency, the circuit follows a negative load reactance path, and for the higher, it follows a positive load reactance path, and
in the “Tune” part of the circuit, the pair of components are placed in series, and in the “Load” part of the circuit, the pair of components are placed in parallel.

It may be noted that a real solution exists only when r<1. For r>1, an analogous method may be used by first placing a “Load” circuit in parallel, and then a “Tune” circuit in series.

FIG. 3 shows a RF generator 1 as multi-frequency power source which is intended to power the CCP-PS illustrated as a chamber 2. The matching circuit 3 according to the present invention comprises a tune circuit 4 and a load circuit 5. The tune circuit 4 is connected in series to the chamber 2. The load circuit 5 is connected in parallel to the series-connected tune circuit 4 and chamber 2. Thus, the load circuit 5 has one end connected to the RF generator output and the other to signal ground.

The tune circuit 4 comprises a capacitor Cₜᵤₙₑ and an inductor Lₜᵤₙₑ connected in series, and therefore between the chamber 2 and the RF generator 1.

The load circuit 5 comprises a capacitor C_{load} and an inductor L_{load} connected in parallel, and therefore between the RF generator output and signal ground.

Additional pairs of frequencies can be added in this way:
for each additional pair of frequencies, similar circuits are added in parallel for the “Tune” part of the matching circuit, and in series for the “Load” part.
To a first approximation, the other component pairs can be assumed to be an infinite or zero impedance for the “Tune” or “Load” parts, respectively, and can thus be neglected for the initial guess for component values. The residual, finite impedance can then be corrected through an iterative process.

In other words, components values for each pair of frequencies are first determined, then an iterative process is carried out to take into account the probably real contribution of other pairs of frequencies. Alternatively, an ideal solution may be calculated in one step using the full set of circuit equations.

An example circuit for which matching is obtained for four frequencies is shown in FIG. 4. In the “Tune” circuit, series connected inductor-capacitor pairs are connected in parallel. As a first approximation, at frequencies far below and far above their resonant frequency (ω=(LC)^{1/2}), each series-connected inductor-capacitor pair acts like an open circuit, and can be ignored when guessing the correct values for the other series-connected inductor-capacitor pair. On FIG. 4, the capacitor Cₜᵤₙₑ₁ and the inductor Lₜᵤₙₑ₁ allow the adaptation of a first pair of frequencies. The capacitor Cₜᵤₙₑ₂ and the inductor Lₜᵤₙₑ₂ allow the adaptation of a second pair of frequencies.

In the “Load” circuit, parallel-connected inductor-capacitor pairs are then connected in series. As a first approximation, at frequencies far below and far above their resonant frequency, each parallel-connected inductor-capacitor pair acts like a short circuit, and can be ignored when guessing the correct values for the other parallel-connected inductor-capacitor pair. The capacitor C_{load1} and the inductor L_{load1} allow the adaptation of the first pair of frequencies. The capacitor C_{load2} and the inductor L_{load2} allow the adaptation of the second pair of frequencies.

As an example according to the present invention, it is described now a case of matching a plasma chamber modelled by a 2 Ω resistor in series with a 15 nH inductor and a 700 pF capacitor. When normalized to Z=50Ω, these components give the following values:

z_{chamber}(15 MHz)=0.04−j0.275

z_{chamber}(30 MHz)=0.04−j0.095

z_{chamber}(60 MHz)=0.04+j0.037

z_{chamber}(90 MHz)=0.04+j0.119

and are presented on the Smith Chart in FIG. 5. This combination models for example a realistic small area laboratory reactor. For this example, it is desired that the RF generator see a real 50 ohms load at 15, 30, 60 and 90 MHz, simultaneously. The desired path for these four frequencies can be seen in FIG. 5. The two dotted lines concern the paths of the two solutions that will both provide matching. Among the pair of frequencies 15 MHz and 30 MHz, the negative load reactance path is followed by the 15 MHz frequency. The positive load reactance path is followed by the 30 MHz frequency. For the pair of frequencies 60 MHz and 90 MHz, the negative load reactance path is followed by the 60 MHz frequency. The positive load reactance path is followed by the 90 MHz frequency.

As can be seen from FIG. 5, the two pairs of components that are chosen for the Tune circuit should give normalized impedance values of z=+/−0.196 (x_{match}=(r−r²)^{1/2} with r=0.04) at each corresponding pair of frequencies. Therefore, the normalized impedance of the Tune circuit should be equal to:

x_{Tune}(15 MHz)=j0.085

x_{Tune} (30 MHz)=j0.285

x_{Tune} (60 MHz)=−j0.227

x_{Tune} (90 MHz)=j0.071

For example, for the pair of frequencies 15 and 30 MHz, the values of capacitor Cₜᵤₙₑ₁ and the inductor Lₜᵤₙₑ₁ are determined to reach simultaneously and respectively the first “negative” point 6 and the first “positive” point 7 as depicted on FIG. 5. Then, the inductor L_{load1} and capacitor C_{load1} are used to simultaneously reach the resistance 9 from the second “negative” point 8 for 15 MHz, and to reach the resistance 9 from the second “positive” point 10 for the frequency 30 MHz.

Initially, values are chosen assuming that the contribution of the circuit in parallel is negligible. Through an iterative process to take into account the contribution at frequencies 15 and 30 MHz of the residual impedance of the components chosen for the frequencies at 60 and 90 MHz (and vice-versa), the final chosen values are:

C_{Tune1}=9.32 nF

L_{Tune1}=54.6 nH

C_{Tune2}=148.0 pF

L_{Tune2}=28.2 nH

A similar process is performed for the Load circuit, and the following final component values are chosen:

C_{Load1}=971 pF

L_{Load1}=52.6 nH

C_{Load2}=556 pF

L_{Load2}=9.29 nH

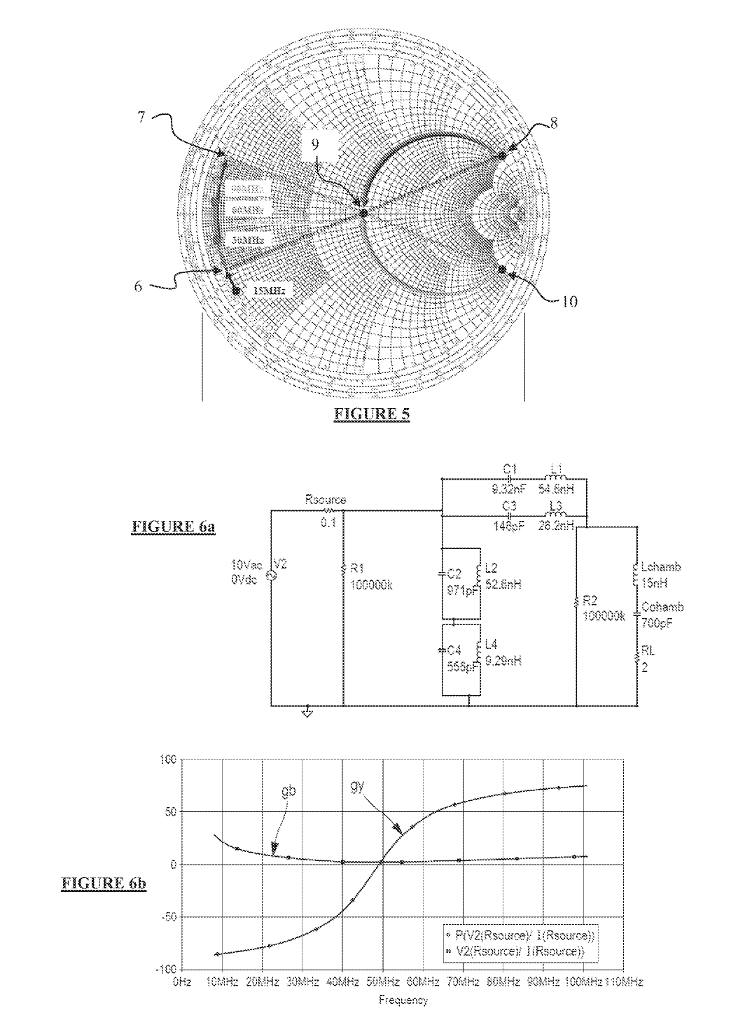

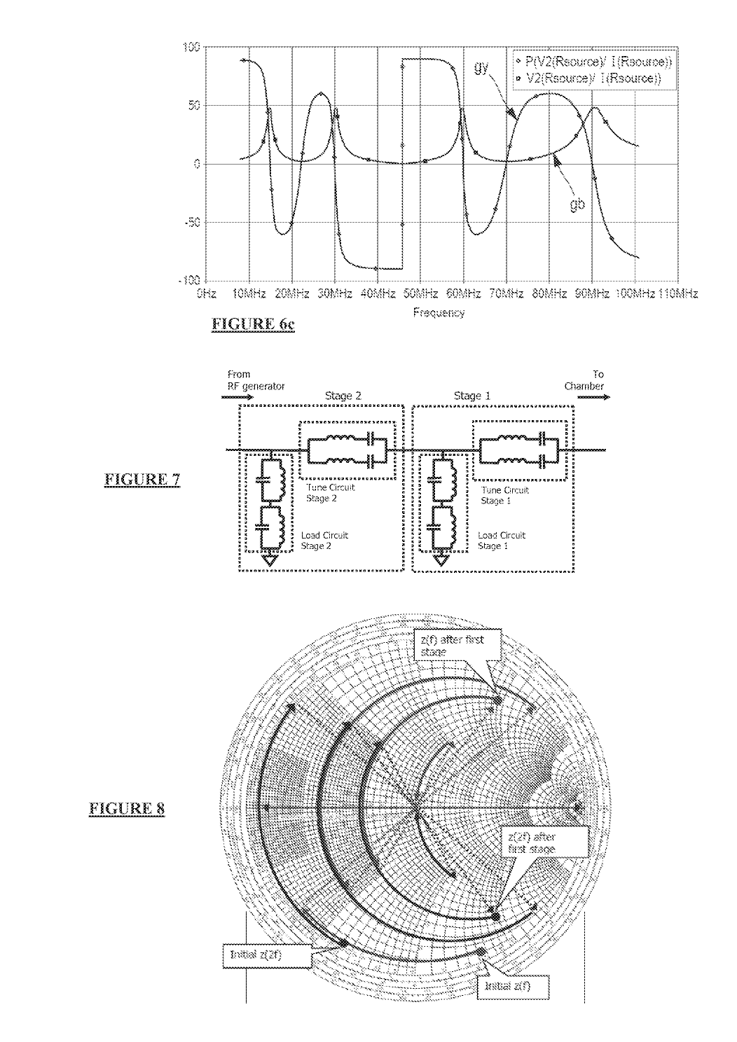

A computer simulation of this circuit (shown in FIG. 6a) shows that indeed, within the approximations made in the original reading of the Smith chart, the circuit designed transforms the impedance of the load (FIG. 6b) such that the source sees a load impedance of 50+j0 at the four frequencies chosen (FIG. 6c). FIG. 6b shows the magnitude of the load impedance seen at the chamber feedthrough. It comprises a concave curve gb varying between a value of 25 ohms at 10 MHz to a value of around 10 ohms at 100 MHz. A minimum of around zero ohm is obtained at 50 MHz. The curve denoted “gy” indicates the phase of the impedance seen at the chamber feedthrough, which has the form of an “S” shape between −90 degrees at 9 MHz to 75 degrees at 100 MHz; the inflection point being for zero ohm at 50 MHz.

On FIG. 6c, it can be seen that for each of the frequencies 15, 30, 60 and 90 MHz, the magnitude of the impedance (curve gb) is 50 ohms, and the phase (gy) is 0 degrees.

For some reactor designs, particularly those with a very large negative reactance, it may be difficult to perform the above matching technique, as for any Tune circuit (i.e. any series-connected component pair) the impedance at the lower frequency is always more negative than the one at the higher frequency. The threshold design situation exists when with no Cₜᵤₙₑ₁ is present, and a certain value of Lₜᵤₙₑ₁ displaces the two impedances exactly to ±x_{match}. To describe this as a threshold condition, one chooses a value of Lₜᵤₙₑ₁ which displaces the two impedances so that they are complex conjugates (z=r±xₜₑₛₜ). Removing the normalization (Z=(r+ix)Z₀=R+iX), this gives:

$$X ( {ω}_{1} ) + {ω}_{1} L = - X ( {ω}_{2} ) - {ω}_{2} L$$

$$L = - \frac{X ( {ω}_{2} ) + X ( {ω}_{1} )}{{ω}_{2} + {ω}_{1}}$$

The resulting reactances after adding the inductance (X(ω₁)+ω₁L and X(ω₂)+ω₂L) must be a pair of points which fall between the points ±X_{match}, as the subsequent addition of a capacitor can only make the separation between these points larger. Selecting the value of inductance above, this condition can be expressed as:

$$X ( {ω}_{2} ) - \frac{{ω}_{2}}{{ω}_{2} + {ω}_{1}} ( X ( {ω}_{2} ) + X ( {ω}_{1} ) ) \leq {X}_{match}$$

ωᵢ being the i-th angular frequency, and X(ωᵢ) being the reactance of the load at angular frequency ωᵢ.

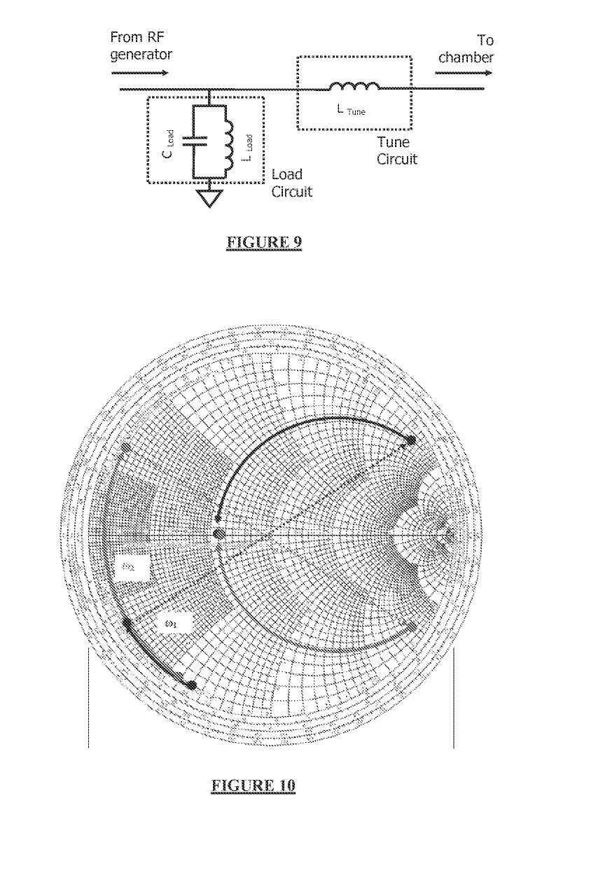

If this equation is not satisfied, then no values can be chosen for Cₜᵤₙₑ₁ and Lₜᵤₙₑ₁ to obtain a perfect match in a single stage. To address such design situations in the requirement of a perfect match, FIG. 7 shows the use of a multistage, multi-frequency match box. In this design, multiple stages are connected in series, each with an internal design similar to that of FIG. 4. Each stage contains a “Load” and “Tune” set of components. It should be noted that some components in a stage may in fact be set to a null value (or removed) for simplicity's sake. In the simplest case, this may consist of adding a single component in series or in parallel at the RF input of the chamber, i.e. setting most components to null values in stage 1.

The impedance progression that results from the use of a multistage circuit (as in FIG. 7) is shown in the Smith chart of FIG. 8. The impedances seen at the input to stage 1 (rather than 50Ω) for f and 2f contain slightly larger real parts compared to their initial value, but oppositely signed reactive parts. On the Smith chart of FIG. 8, the dotted lines represent the transformation of the impedance to an admittance (to add a parallel admittance circuit). The initial point z(f) follows the negative load reactance path to reach an intermediate impedance. This negative load reactance path comprises a first rotation, a first impedance-to-admittance transformation, a second rotation and a second impedance-to-admittance transformation. Similarly, the initial point z(2f) follows the positive load reactance path to reach an intermediate impedance. This positive load reactance path comprises a first rotation, a first impedance-to-admittance transformation, a second rotation and a second impedance-to-admittance transformation.

The selection of the components for stage 2 can now be made, with the existence of a solution for the circuit components now guaranteed.

Another strategy that can be used when a perfect solution does not exist- or in the case where a less ideal match can be accepted for the sake of using fewer components—is to attempt to obtain the best possible match using fewer components. An example of such a circuit is shown in FIG. 9, where the component Cₜᵤₙₑ₁ has been eliminated. With respect to FIG. 3, only the inductor Lₜᵤₙₑ is present in the tune circuit in series to the chamber. To obtain the best possible match with this circuit for the two frequencies desired, one would select the value of Lₜᵤₙₑ to displace the chamber impedances at ω₁ and ω₂ to be complex conjugates ±X_{conj}, as already described above:

$$X ( {ω}_{1} ) + {ω}_{1} L = - X ( {ω}_{2} ) - {ω}_{2} L = \pm {X}_{conj}$$

$$L = - \frac{X ( {ω}_{2} ) + X ( {ω}_{1} )}{{ω}_{2} + {ω}_{1}}$$

L being an inductance, ωᵢ being the i-th angular frequency, and X(ωᵢ) being the reactance of the load at an angular frequency ωᵢ.

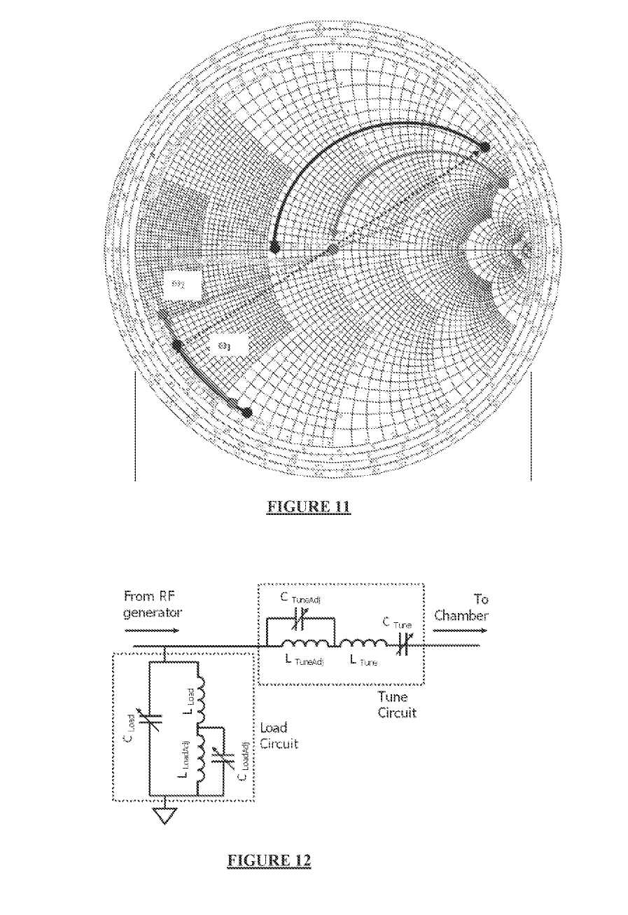

When this value is chosen for L_{Tune}, the two values C_{Load} and L_{Load} can be chosen to give the best possible match (in which case, the impedance seen by the source will be completely real). This design strategy is well-visualized using the Smith chart, and is shown in FIG. 10. ω₁ and ω₂ respectively follow the negative load reactance path and the positive load reactance paths to reach the two solutions that provide the best possible match in the Smith chart.

In this case, additionally, one may consider the example of a test point of impedance r+xₜₑₛₜ, where r is the impedance of the load and xₜₑₛₜ is the normalized impedance after the Tune circuit when choosing the inductor L as described above. The power matching can immediately be known from the equivalent admittance y at this test point as given by:

y=g+ibₜₑₛₜ=1/r+xₜₑₛₜ

r_{match}=1/g

where g and bₜₑₛₜ are the normalized conductance and susceptance after the Tune circuit. r_{match} is then the normalized resistance obtained when the normalized susceptance bₜₑₛₜ is eliminated using a load circuit.

Using this value, one can calculate the minimum possible power reflection coefficient Γ when removing this one component by:

$$Γ = \vert \frac{1 - {r}_{match}}{1 + {r}_{match}} \vert$$

Analogously to removing a capacitor from the Tune circuit, an imperfect match can be obtained using one less component by removing L_{Load} from the circuit of FIG. 3. However, a clear design strategy is less clear in this case, as can be seen from the Smith chart representing this circuit in FIG. 11. The relationship between the admittances of the Load circuit (namely, that the admittance will become more positive with frequency) means that this configuration can only be useful for a very specific pair of impedances as seen after the Tune circuit. Additionally, the real part of the admittances seen at the two frequencies after the Tune circuit will not have the same magnitude, and so the reflection coefficient will not be the same, and will be difficult to predict in advance.

Finally, in practice, the impedance of the chamber and plasma at the frequencies for which matching is required will not be perfectly known, and/or may be subject to drift. For this reason, all the Load and Tune capacitors in the circuits should be adjustable. Although the use of adjustable inductors would allow for a perfect match (or at least the best possible), these are not standard components. Alternatively, one may split the inductor into two inductors connected in series (for example, into L_{Tune} and L_{TuneAdj}) with a total value equal to the calculated, ideal inductance, and then place an adjustable capacitor (C_{TuneAdj}) in parallel to one of them (L_{TuneAdj}). This may be equivalently done for the Load circuit (placing C_{LoadAdj} in parallel with L_{LoadAdj}), and these together with C_{Tune} and C_{Load} giving the small degree of adjustment necessary to correct these inductive components and to give better matching at all the desired frequencies. C_{TuneAdj} and C_{LoadAdj} should be appropriately small so that they have a large impedance value relative to the inductors at the frequencies of interest. FIG. 12 is based on FIG. 3 where the standard capacitors Cₜᵤₙₑ and C_{load} are replaced by adjustable capacitors, in addition to the adjustable capacitors added to emulate variable inductors. As it is easier in practice to obtain an adjustable capacitor than an adjustable inductor, each inductor is associated to an adjustable capacitor. The tune inductor is associated with an adjustable capacitor C_{tuneadj} (partially in parallel). The load inductor is associated with an adjustable capacitor C_{loadadj} (partially in parallel).

Numerous variations and modifications will become apparent to those skilled in the art once the above disclosure is fully appreciated. It is intended that the following claims be interpreted to embrace all such variations and modifications.

1-17. (canceled)

18. A matching circuit to adapt electrical impedance simultaneously for at least one pair of a higher and a lower frequencies between a load and a generator;
said matching circuit comprises at least a “load and tune” L-type stage comprising:
a “tune circuit” connected in series to the load and comprising at least one of or both an inductor and a capacitor in series;
a “load circuit” connected in parallel to the series-connected “tune circuit” and load, and comprising at least one of or both an inductor and a capacitor in parallel;
the component values of the tune and load circuits are chosen such that, for the lower frequency, the matching circuit follows a negative load reactance path in a Smith chart, and for the higher frequency, the matching circuit follows a positive load reactance path in the Smith chart;
the “negative load reactance” solution being the one for which the impedance added in series to the load results in the sum of the two having a negative reactance whereas the inverse is true for the “positive load reactance” solution; and
the higher and lower frequencies are a fundamental frequency with one of its harmonics and in that the load is a capacitively coupled plasma reactor.

19. The matching circuit according to claim 18, characterized in that for each additional pair of frequencies, the matching circuit comprises an additional tune circuit in parallel to the first tune circuit, and an additional load circuit in series with the first load circuit.

20. The matching circuit according to claim 18, characterized in that it comprises multiple stages connected in series.

21. The matching circuit according to claim 18, characterized in that at least one of the stage components is adjustable.

22. The matching circuit according to claim 21, characterized in that the adjustable component is a capacitor.

23. The matching circuit according to claim 21, characterized in that a variable inductor is obtained in the tune circuit by splitting the inductor into two standard inductors in series, and adding an adjustable capacitor in parallel to one of these standard inductors.

24. The matching circuit according to claim 21, characterized in that a variable inductor is obtained in the load circuit by splitting the inductor into two standard inductors in series, and adding an adjustable capacitor in parallel to one of these standard inductors.

25. A method for designing a matching circuit to adapt electrical impedance simultaneously for at least a pair of a higher and a lower frequencies between a load and a generator; said matching circuit comprises at least a “load and tune” L-type stage comprising:
a “tune circuit” connected in series to the load and comprising at least one of or both an inductor and a capacitor in series;
a “load circuit” connected in parallel to the series-connected “tune circuit” and load, and comprising at least one of or both an inductor and a capacitor in parallel;
wherein the method comprises the step of using a Smith chart to determine the components values of the tune and load circuits by following a negative load reactance path for the lower frequency, and by following the positive load reactance path for the higher frequency the higher and lower frequencies being a fundamental frequency with one of its harmonics and the load being a capacitively coupled plasma reactor.

26. The method according to claim 25, characterized in that for each additional pair of frequencies, an additional tune circuit is added in parallel to the first tune circuit, and an additional load circuit is added in series to the first load circuit.

27. The method according to claim 26, characterized in that the component values of the additional components are calculated by first assuming that the values for the first tune circuit or the first load circuit are infinite or zero impedance respectively, then an iterative process is carried out to correct the additional components' values.

28. The method according to claim 25, characterized in that a perfect match is obtainable in a single stage when:
$$X ( {ω}_{2} ) - \frac{{ω}_{2}}{{ω}_{2} + {ω}_{1}} ( X ( {ω}_{2} ) + X ( {ω}_{1} ) ) \leq {X}_{match} X ( {ω}_{1} ) ) \leq {X}_{match}$$
±X_{match} being the two solutions that provide matching in a Smith chart, one following the negative load reactance path, and one following the positive load reactance path; ωᵢ being the i-th angular frequency, and X(ωᵢ) being the reactance of the load at the angular frequency ωᵢ.

29. A system comprising:
a matching circuit according to claim 1;
a capacitively coupled plasma reactor; and
a generator for simultaneously powering the capacitively coupled plasma reactor with said at least one pair of a lower and higher frequencies, said frequencies being a fundamental frequency with one of its harmonics.
